(19) United States
(12) Patent Application Publication
(10) Pub. No.: US 2010/0269900 A1
(43) Pub. Date: Oct. 28, 2010

(54) PHOTOVOLTAIC CELL FRONT FACE SUBSTRATE AND USE OF A SUBSTRATE FOR A PHOTOVOLTAIC CELL FRONT FACE

(75) Inventors: Eric Mattmann, Paris (FR); Ulrich Billert, Garches (FR); Nikolas Janke, Herzogenrath (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN GLASS FRANCE, Courbevoie (FR)

(21) Appl. No.: 12/373,528

(22) PCT Filed: Jul. 25, 2008
(86) PCT No.: PCT/FR2008/051398

§ 371 Date: Apr. 2, 2009

(30) Foreign Application Priority Data
Jul. 27, 2007 (FR) 0756767
Nov. 20, 2007 (FR) 0759182

(51) Int. Cl. H01L 31/0216; H01L 31/18

(52) U.S. Cl. 136/256; 438/72; 257/E31.119

(57) ABSTRACT

The invention relates to a photovoltaic cell (1) having an absorbent photovoltaic material, said cell comprising a front face substrate (10), especially a transparent glass substrate, having, on a main surface, a transparent electrode coating (100) consisting of a thin-film stack that includes a metallic functional layer (40), especially one based on silver, and at least two antireflection coatings (20, 60), characterized in that the antireflection coating (20) placed beneath the metallic functional layer (40) in the direction of the substrate has an optical thickness equal to about one eighth of the maximum absorption wavelength of the photovoltaic material and the antireflection coating (60) placed above the metallic functional layer (40) on the opposite side from the substrate has an optical thickness equal to about one half of the maximum absorption wavelength of the photovoltaic material.

The invention relates to a photovoltaic cell front face substrate, especially a transparent glass substrate.

In a photovoltaic cell, a photovoltaic system having a photovoltaic material which produces electrical energy through the effect of incident radiation is positioned between a backplate substrate and a front face substrate, this front face substrate being the first substrate through which the incident radiation passes before it reaches the photovoltaic material.

In a photovoltaic cell, the front face substrate usually has, beneath a main surface turned toward the photovoltaic material, a transparent electrode coating in electrical contact with the photovoltaic material placed beneath when the main direction of arrival of the incident radiation is considered to be via the top.

This front face electrode coating thus constitutes for example the negative terminal of the photovoltaic cell.

Of course, the photovoltaic cell also has in the direction of the backplate substrate an electrode coating that then constitutes the positive terminal of the photovoltaic cell, but in general the electrode coating of the backplate substrate is not transparent.

Within the context of the invention, the term “photovoltaic cell” should be understood to mean any assembly of constituents that produces an electrical current between its electrodes by solar radiation conversion, whatever the dimensions of this assembly and whatever the voltage and the intensity of the current produced, and in particular whether or not this assembly of constituents has one or more internal electrical connections (in series and/or in parallel).

The notion of a “photovoltaic cell” within the context of the present invention is therefore equivalent here to that of a “photovoltaic module” or a “photovoltaic panel”.

The material normally used for the transparent electrode coating of the front face substrate is in general a material based on a TCO (transparent conductive oxide), such as for example a material based on indium tin oxide (ITO) or based on aluminum-doped zinc oxide (ZnO:Al) or boron-doped zinc oxide (ZnO:B) or based on fluorine-doped tin oxide (SnO₂:F).

These materials are deposited chemically, for example by CVD (chemical vapor deposition), optionally PECVD (plasma-enhanced CVD), or physically, for example by vacuum deposition by cathode sputtering, optionally magnetron sputtering (i.e. magnetically enhanced sputtering).

However, to obtain the desired electrical conduction, or rather the desired low resistance, the electrode coating made of a TCO-based material must be deposited with a relatively large physical thickness, of around 500 to 1000 nm and even sometimes higher, this being costly as regards the cost of these materials when they are deposited as layers with this thickness.

When the deposition process requires a heat supply, this further increases the manufacturing cost.

Another major drawback of electrode coatings made of a TCO-based material lies in the face that, for a chosen material, its physical thickness is always a compromise between the electrical conduction finally obtained and the transparency finally obtained, since the greater the physical thickness, the higher the conductivity but the lower the transparency, while conversely, the lower the physical thickness, the higher the transparency but the lower the conductivity.

It is therefore not possible with electrode coatings made of a TCO-based material to independently optimize the conductivity of the electrode coating and its transparency.

The prior art of international patent application WO 01/43204 teaches a process for manufacturing a photovoltaic cell in which the transparent electrode coating is not made of a TCO-based material but consists of a thin-film stack deposited on a main face of the front face substrate, this coating comprising at least one metallic functional layer, especially a silver-based one, and at least two antireflection coatings, said antireflection coatings each comprising at least one antireflection layer, said functional layer being placed between the two antireflection coatings.

This process is noteworthy in that it provides for at least one highly refringent layer made of an oxide or nitride to be deposited beneath the metallic functional layer and above the photovoltaic material when considering the direction of the incident light entering the cells from above.

That document provides an exemplary embodiment in which two antireflection coatings which flank the metallic functional layer, namely the antireflection coating placed beneath the metallic functional layer in the direction of the substrate and the antireflection coating placed above the metallic functional layer on the opposite side from the substrate, each comprise at least one layer made of a highly refringent material, in this case the zinc oxide (ZnO) or silicon nitride (Si₃N₄).

However, this solution can be further improved.

Observing that the absorption of the usual photovoltaic materials differs from one material to another, the inventors have sought to define the essential optical characteristics needed for the definition of a thin-film stack of the type presented above in order to form an electrode coating or a photovoltaic cell front face.

The present invention thus consists, in the case of a photovoltaic cell front face substrate, in defining the optical path for obtaining the highest efficiency of the photovoltaic cell as a function of the photovoltaic material chosen.

Thus, one subject of the invention, in its broadest acceptance, is a photovoltaic cell having an absorbent photovoltaic material as claimed in claim 1. This cell comprises a front face substrate, especially a transparent glass substrate, having, on a main surface, a transparent electrode coating consisting of a thin-film stack that includes a metallic functional layer, especially one based on silver, and at least two antireflection coatings, said antireflection coatings each comprising at least one antireflection layer, said functional layer being placed between the two antireflection coatings. The antireflection coating placed beneath the metallic functional layer in the direction of the substrate has an optical thickness equal to about one eighth of the maximum absorption wavelength λₘ of the photovoltaic material and the antireflection coating placed above the metallic functional layer on the opposite side from the substrate has an optical thickness equal to about one half of the maximum absorption wavelength λₘ of the photovoltaic material.

In a preferred embodiment, the maximum absorption wavelength λₘ of the photovoltaic material is however weighted by the solar spectrum.

In this embodiment, the photovoltaic cell is characterized in that the antireflection coating placed beneath the metallic functional layer in the direction of the substrate has an optical thickness equal to about one eighth of the maximum wavelength λ_{M} of the product of the absorption spectrum of the photovoltaic material multiplied by the solar spectrum and the antireflection coating placed above the metallic functional layer on the opposite side from the substrate has an optical thickness equal to about one half of the maximum wavelength λ_{M} of the product of the absorption spectrum of the photovoltaic material multiplied by the solar spectrum.

Thus, according to the invention, an optimum optical path is defined as a function of the maximum absorption wavelength λₘ of the photovoltaic material or preferably as a function of the maximum wavelength λ_{M} of the product of the absorption spectrum of the photovoltaic material multiplied by the solar spectrum, so as to obtain the highest efficiency of the photovoltaic cell.

The solar spectrum to which reference is made here is the AM 1.5 solar spectrum as defined by the ASTM standard.

Within the context of the present invention, the term “coating” should be understood to mean that there may be a single layer or several layers of different materials within the coating.

Within the context of the present invention, the term “antireflection layer” should be understood to mean that, from the standpoint of its nature, the material is “nonmetallic” i.e. it is not a metal. Within the context of the invention, this term should be understood not to introduce any limitation on the resistivity of the material, which may be that of a conductor (in general, ρ<10⁻³ Ω·cm), that of an insulator (in general, ρ>10⁹ Ω·cm) or that of a semiconductor (in general between the above two values).

Completely surprisingly and independently of any other characteristic, the optical path of an electrode coating and a thin-film stack with a functional monolayer, which has an antireflection coating placed above the functional metallic layer with an optical thickness equal to about four times the optical thickness of the antireflection coating placed beneath the metallic functional layer, makes it possible to improve the efficiency of the photovoltaic cell, together with its improved resistance to the stresses generated during operation of the cell.

Said antireflection coating placed above the metallic functional layer thus preferably has an optical thickness of between 3.1 and 4.6 times the optical thickness of the antireflection coating placed beneath the metallic functional layer, these values being inclusive, or even the antireflection coating placed above the metallic functional layer has an optical thickness of between 3.2 and 4.2 times the optical thickness of the antireflection coating placed beneath the metallic functional layer, these values being inclusive.

The purpose of the coatings that flank the metallic functional layer is to “antireflect” this metallic functional layer. This is why they are called “antireflection coatings”.

Indeed, although the functional layer enables by itself the desired conductivity of the electrode coating to be obtained, even with a small physical thickness (of the order of 10 nm), said layer will strongly oppose the passage of light.

In the absence of such an antireflection system, the light transmission would then be much too low and the light reflection much too high (in the visible and in the near infrared, since it is a question of producing a photovoltaic cell).

The term “optical path” has here a specific meaning and is used to denote the sum of the various optical thicknesses of the various antireflection coatings subjacent and superjacent to the functional metallic layer of the interference filter thus produced. It will be recalled that the optical thickness of a coating is equal to the product of the physical thickness of the material multiplied by its index when there is only a single layer in the coating, or the sum of the products of the physical thickness of the material of each layer multiplied by its index when there are several layers.

The optical path according to the invention is, in the absolute, a function of the physical thickness of the metallic functional layer, but in fact, within the range of physical thicknesses of the functional metallic layer enabling the desired conductance to be obtained, it turns out that it does not so to speak vary. Thus, the solution according to the invention is suitable when the functional layer is based on silver, is a single layer and has a physical thickness of between 5 and 20 nm, these values being inclusive.

The type of thin-film stack according to the invention is known in the field of architectural or automotive glazing, in order to produce glazing of enhanced thermal insulation of the “low-E (low-emissivity)” and/or “solar control” type.

The inventors thus noticed that certain stacks of the type of those used for low-E glazing in particular could be used to produce electrode coatings for a photovoltaic cell, and in particular the stacks known as “toughenable” stacks or stacks “to be toughened”, i.e. those used when it is desired to subject a toughening heat treatment on the substrate carrying the stack.

Thus, another subject of the present invention is the use of a thin-film stack for architectural glazing having the features of the invention and especially a stack of this type that is “toughenable” or is “to be toughened”, especially a low-E stack, particularly one that is “toughenable” or “to be toughened”, in order to produce a photovoltaic cell front face substrate.

Thus, another subject of the invention is the use of this thin-film stack that has undergone a toughening heat treatment and the use of a thin-film stack for architectural glazing having the features of the invention that has undergone a surface heat treatment of the type of that known from French Patent Application FR 2 911 130.

The term “toughenable” stack or substrate within the context of the present invention should be understood to mean that the essential optical properties and thermal properties (expressed by the resistance per square, which is directly related to the emissivity) are preserved during the heat treatment.

Thus, it is possible on one and the same building façade for example to place close together glazing panels incorporating toughened substrates and untoughened substrates, both coated with the same stack, without it being possible to distinguish one from another by simple visual observation of the color in reflection and/or of the light reflection/transmission.

For example, a stack or substrate coated with a stack having the following changes, before heat treatment and after treatment, will be considered to be toughenable since these changes will not be perceptible to the eye:
a small change in light transmission ΔT_{L} (in the visible) of less than 3%, or even less than 2%; and/or
a small change in light reflection ΔR_{L} (in the visible) of less than 3%, or even less than 2%; and/or
a small change in color (in the Lab system) ΔE={square root over (((ΔL*)²+(Δa*)²+(Δb*)²))} of less than 3 or even less than 2.

A stack or substrate “to be toughened” within the context of the present invention should be understood to mean that the optical and thermal properties of the coated substrate are acceptable after heat treatment, whereas were not, or in any case not all, previously.

For example, a stack, or a substrate coated with a stack, having after the heat treatment the following characteristics will be considered “to be toughened” within the context of the present invention, whereas prior to the heat treatment at least one of these characteristics was not fulfilled:
a high light transmission T_{L} (in the visible) of at least 65%, or 70% or even at least 75%; and/or
a low light absorption (in the visible, defined by 1−T_{L}−R_{L}) of less than 10%, or less than 8% or even less than 5%; and/or
a resistance per square R_{□} at least as good as that of the conductive oxides normally used, and in particular less than 20 Ω/□, or less than 15 Ω/□ or even equal to or less than 10 Ω/□.

Thus, the electrode coating must be transparent. It must therefore have, when mounted on the substrate, minimum average light transmission, between 300 and 1200 nm, of 65%, or even 75% and more preferably 85% and even more especially less than 90%.

If the front face substrate has undergone a heat treatment, especially a toughening heat treatment, before deposition of the thin layers and before it is fitted into the photovoltaic cell, it is quite possible, before this heat treatment, for the substrate coated with the stack acting as electrode coating to be of low transparency. For example, it may have, before this heat treatment, a light transmission in the visible of less than 65% or even less than 50%.

The important point is that the electrode coating should be transparent before heat treatment and be such that it has, after the heat treatment, an average light transmission between 300 and 1200 nm (in the visible) of at least 65%, or even 75% and more preferably 85% and even more especially at least 90%.

Moreover, within the context of the invention, the stack does not have, in the absolute, the best possible light transmission but does have the best possible light transmission within the context of the photovoltaic cell according to the invention.

In one particular embodiment, independently of the fact that:
on the one hand, the antireflection coating placed beneath the metallic functional layer in the direction of the substrate has an optical thickness equal to about one eighth of the maximum absorption wavelength λₘ of the photovoltaic material and that the antireflection coating placed above the metallic functional layer on the opposite side from the substrate has an optical thickness equal to about one half of the maximum absorption wavelength λₘ of the photovoltaic material;
or, on the other hand, the antireflection coating placed beneath the metallic functional layer in the direction of the substrate has an optical thickness equal to about one eighth of the maximum wavelength λ_{M} of the product of the absorption spectrum of the photovoltaic material multiplied by the solar spectrum and the antireflection coating placed above the metallic functional layer on the opposite side from the substrate has an optical thickness equal to about one half of the maximum wavelength λ_{M} of the product of the absorption spectrum of the photovoltaic material multiplied by the solar spectrum,
   the electrode coating according to the invention preferably includes a terminal layer furthest away from the substrate (and in contact with the photovoltaic material) which conducts the current, especially a TCO (transparent conductive oxide)-based layer. Consequently, the charge transport between the electrode coating and the photovoltaic material may be easily controlled and the efficiency of the cell can be consequently improved.

This terminal layer that conducts the current is made of a material having a resistivity ρ (which corresponds to the product of the resistance per square R_{□} of the layer multiplied by its thickness) such that 2×10⁻⁴ Ω·cm≦ρ≦10 Ω·cm, or even such that 1×10⁻⁴ Ω·cm≦ρ≦10 Ω·cm. This terminal layer that conducts the current preferably has an optical thickness representing between 50 and 980 of the optical thickness of the antireflection coating furthest away from the substrate and especially an optical thickness representing between 85 and 98% of the optical thickness of the antireflection coating furthest away from the substrate.

Although this is not recommended, it is not impossible for the entire antireflection coating placed above the metallic functional layer on the opposite side from the substrate to consist of such a terminal layer that conducts the current, so as to simply the deposition process by reducing the number of different layers to be deposited.

In contrast, the antireflection coating placed above the metallic functional layer cannot be in its entirety (over its entire thickness) electrically insulating.

A transparent conductive oxide suitable for implementing this embodiment with a terminal layer that conducts the current is chosen from the list comprising: ITO, ZnO:Al, ZnO:B, ZnO:Ga, SnO₂:F, TiO₂:Nb, cadmium stannate, a mixed tin zinc oxide SnₓZn_{y}O_{z} (in which x, y and z are numbers), optionally doped, for example with antimony Sb, and generally all transparent conductive oxides obtained from at least one of the elements: Al, Ga, Sn, Zn, Sb, In, Cd, Ti, Zr, Ta, W and Mo and especially oxides from one of these elements doped with at least one other of these elements, or mixed oxides of at least two of these elements, optionally doped with at least a third of these elements.

Preferably, said antireflection coating placed above the metallic functional layer has an optical thickness of between 0.45 and 0.55 times the maximum absorption wavelength λₘ of the photovoltaic material, these values being inclusive, and more preferably said antireflection coating placed above the metallic functional layer has an optical thickness of between 0.45 and 0.55 times the maximum wavelength λ_{M} of the product of the absorption spectrum of the photovoltaic material multiplied by the solar spectrum, these values being inclusive.

The antireflection coating placed beneath the metallic functional layer has an optical thickness of between 0.075 and 0.175 times the maximum absorption wavelength λₘ of the photovoltaic material, these values being inclusive, and preferably said antireflection coating placed beneath the metallic functional layer has an optical thickness of between 0.075 and 0.175 times the maximum wavelength λ_{M} of the product of the absorption spectrum of the photovoltaic material multiplied by the solar spectrum, these values being inclusive.

The antireflection coating placed beneath the metallic functional layer may also have a chemical barrier function, acting as a barrier to diffusion, and in particular to the diffusion of sodium coming from the substrate, therefore protecting the electrode coating, and more particularly the functional metallic layer, especially during any heat treatment, especially toughening heat treatment.

In another particular embodiment, the substrate includes, beneath the electrode coating, a base antireflection layer having a low refractive index close to that of the substrate, said base antireflection layer being preferably based on silicon oxide or based on aluminum oxide or based on a mixture of the two.

Furthermore, this dielectric layer may constitute a chemical diffusion barrier layer, and in particular a barrier to the diffusion of sodium coming from the substrate, therefore protecting the electrode coating, and more particularly the functional metallic layer, especially during any heat treatment, especially a toughening heat treatment.

Within the context of the invention, a dielectric layer is a layer which does not participate in the electric charge displacement (electrical current) or one in which the effect of participation in the electric charge displacement may be considered to be zero compared with that of the other layers of the electrode coating.

Moreover, this base antireflection layer preferably has a physical thickness of between 10 and 300 nm or between 35 and 200 nm and even more preferably between 50 and 120 nm.

The metallic functional layer is preferably deposited in a crystallized form on a thin dielectric layer which is also preferably crystallized (therefore called a “wetting layer” as it promotes the suitable crystalline orientation of the metallic layer deposited on top).

This metallic functional layer may be based on silver, copper or gold, and may optionally be doped with at least another of these elements.

In the usual manner, “doping” is understood to mean that an element is present in an amount of less than 10% as molar mass of metallic element in the layer and the expression “based on” is understood in the usual manner to mean a layer containing predominantly the material, i.e. containing at least 50% of this material as molar mass. The expression “based on” thus covers the doping.

The thin-film stack producing the electrode coating is a functional monolayer coating, i.e. a single functional layer—it cannot be a functional multi-layer.

The functional layer is thus preferably deposited above, or even directly on, an oxide-based wetting layer, especially one based on zinc oxide, which is optionally doped, optionally with aluminum.

The physical (or actual) thickness of the wetting layer is preferably between 2 and 30 nm and more preferably between 3 and 20 nm.

This wetting layer is a dielectric and is a material preferably having a resistivity ρ (defined by the product of the resistance per square of the layer multiplied by its thickness) such that 0.5 Ω·cm≦ρ≦200 Ω·cm or such that 50 Ω·cm≦ρ≦200 Ω·cm.

The stack is generally obtained by a succession of films deposited using a vacuum technique such as sputtering, optionally magnetron sputtering. It is also possible to provide one or even two very thin coatings called “blocking coatings” that do not form part of the antireflection coatings, which is (are) placed directly under, onto or on each side of the functional, especially silver-based, metallic layer, the coating subjacent to the functional layer, in the direction of the substrate, as tie, nucleating and/or protective coating during the possible heat treatment carried out after the deposition, and the coating superjacent to the functional layer as protective or “sacrificial” coating so as to prevent the functional metallic layer from being impaired by attack and/or migration of oxygen from a layer above it, especially during any heat treatment, or even also by migration of oxygen if the layer above it is deposited by sputtering in the presence of oxygen.

Within the context of the present invention when it is specified that a layer or coating (comprising one or more layers) is deposited directly beneath or directly on another deposited layer or coating, there can be no interposition of another layer between these two deposited layers or coatings.

Preferably, at least one blocking coating is based on Ni or on Ti or is based on an Ni-based alloy, especially based on an NiCr alloy.

Preferably, the coating beneath the metallic functional layer in the direction of the substrate and/or the coating above the metallic functional layer comprise/comprises a layer based on a mixed oxide, in particular based on a zinc tin mixed oxide or an indium tin mixed oxide (ITO).

Moreover, the coating beneath the metallic functional layer in the direction of the substrate and/or the coating above the metallic functional layer may comprise a layer having a high refractive index, especially greater than or equal to 2.2, such as for example a layer based on silicon nitride, optionally doped, for example with aluminum or zirconium.

Moreover, the coating beneath the metallic functional layer in the direction of the substrate and/or the coating above the metallic functional layer may include a layer having a very high refractive index, especially equal to or greater than 2.35, such as for example a layer based on titanium oxide.

The substrate may include a coating based on a photovoltaic material above the electrode coating on the opposite side from the front face substrate.

A preferred structure of a front face substrate according to the invention is thus of the type: substrate/(optional antireflection base layer)/electrode coating/photovoltaic material, or else of the type: substrate/(optional antireflection base layer)/electrode coating/photovoltaic material/electrode coating.

In one particular embodiment, the electrode coating consists of a stack for architectural glazing, especially a “toughenable stack” for architectural glazing or stack for architectural glazing “to be toughened”, and in particular a low-E stack, especially a “toughenable” low-E stack or a low-E stack “to be toughened”, this thin-film stack having the features of the invention.

The present invention also relates to a substrate for a photovoltaic cell according to the invention, especially a substrate for architectural glazing coated with a thin-film stack having the features of the invention, especially a “toughenable” substrate for architectural glazing or a substrate for architectural glazing “to be toughened” having the features of the invention, and in particular a low-E substrate, especially a “toughenable” low-E substrate or a low-E substrate “to be toughened” having the features of the invention.

Thus, the subject of the present invention is also this substrate for architectural glazing coated with a thin-film stack that has the features of the invention and has undergone a toughening heat treatment, and also this substrate for architectural glazing coated with a thin-film stack having the features of the invention that has undergone a heat treatment of the type of that known from French Patent Application FR 2 911 130.

All the layers of the electrode coating are preferably deposited by a vacuum deposition technique, but it is not however excluded for the first layer or first layers of the stack to be able to be deposited by another technique, for example by a thermal deposition technique of the pyrolysis type or by CVD, optionally under vacuum, and optionally plasma-enhanced.

Advantageously, the electrode coating according to the invention having a thin-film stack is moreover much more mechanically resistant than a TCO electrode coating. Thus, the lifetime of the photovoltaic cell may be increased.

Advantageously, the electrode coating according to the invention with a thin-film stack has moreover an electrical resistance at least as good as that of the TCO conductive oxides normally used. The resistance per square R_{□} of the electrode coating according to the invention is between 1 and 20 Ω/□ or even between 2 and 15 Ω/□, for example around 5 to 8 Ω/□.

Advantageously, the electrode coating according to the invention having a thin-film stack has moreover a light transmission in the visible at least as good as that of the TCO conductive oxides normally used. The light transmission in the visible of the electrode coating according to the invention is between 50 and 98%, or even between 65 and 95%, for example around 70 to 90%.

The details and advantageous features of the invention will emerge from the following nonlimiting examples, illustrated by the figures appended herewith:

FIG. 1 illustrates a photovoltaic cell front face substrate of the prior art coated with an electrode coating made of a transparent conductive oxide and having a base antireflection layer;

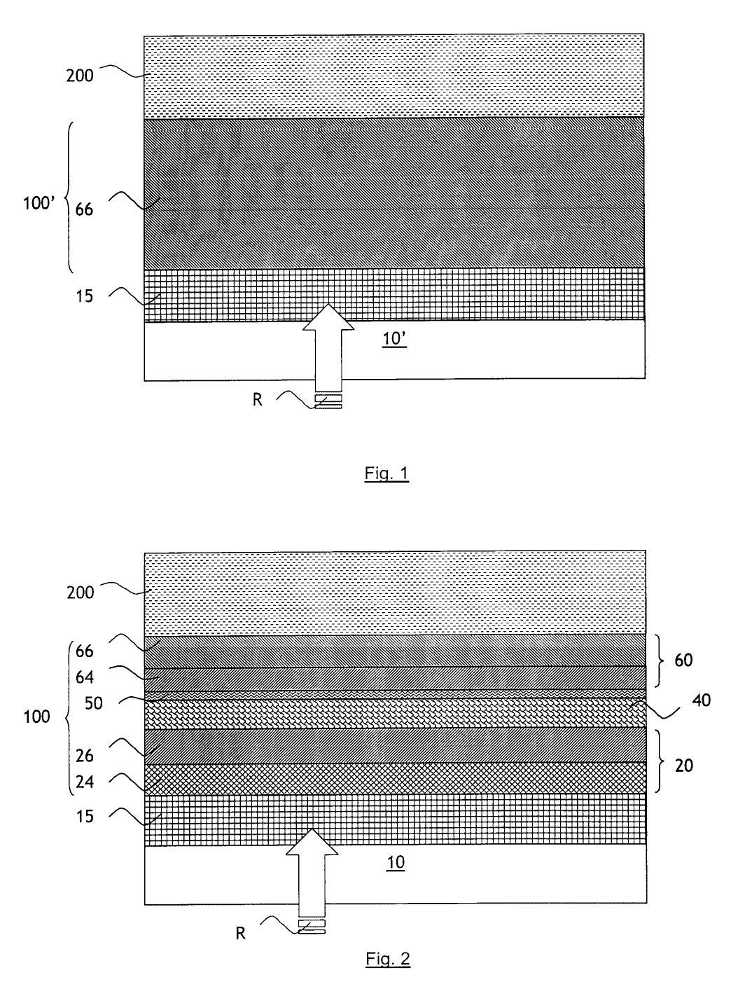

FIG. 2 illustrates a photovoltaic cell front face substrate according to the invention coated with an electrode coating consisting of a functional monolayer thin-film stack and having a base antireflection layer;

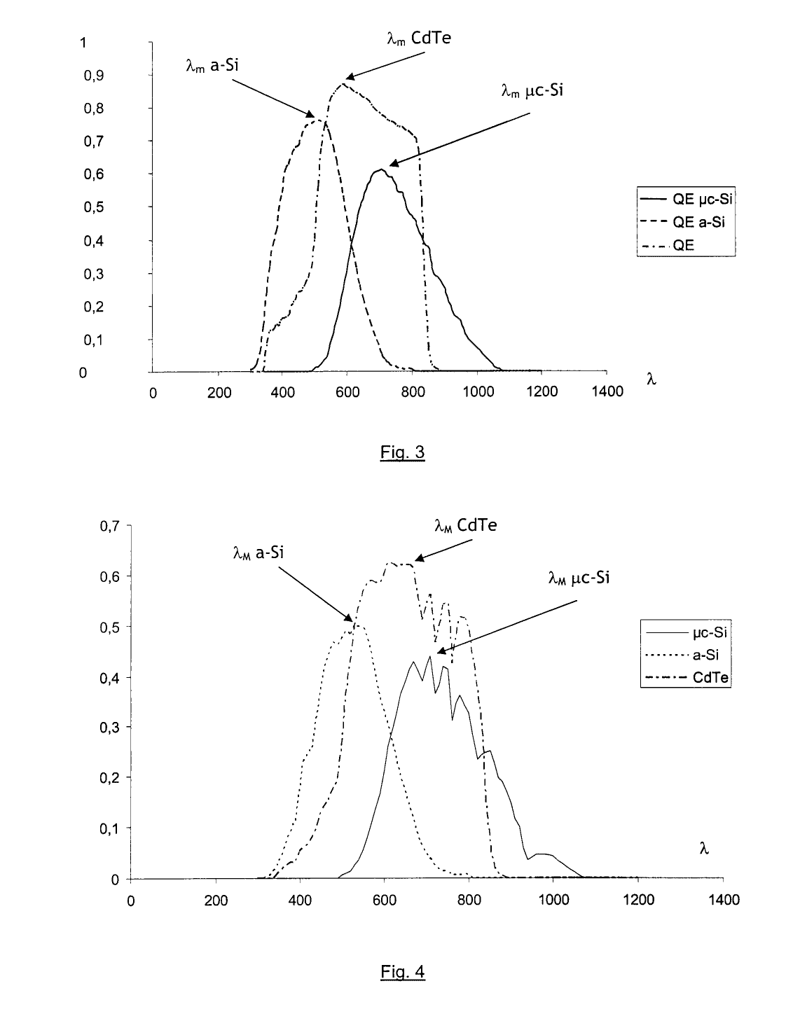

FIG. 3 illustrates the quantum efficiency curve for three photovoltaic materials;

FIG. 4 illustrates the actual yield curve corresponding to the product of the absorption spectrum of these three photovoltaic materials multiplied by the solar spectrum;

FIG. 5 illustrates the principle of the durability test for the photovoltaic cells; and

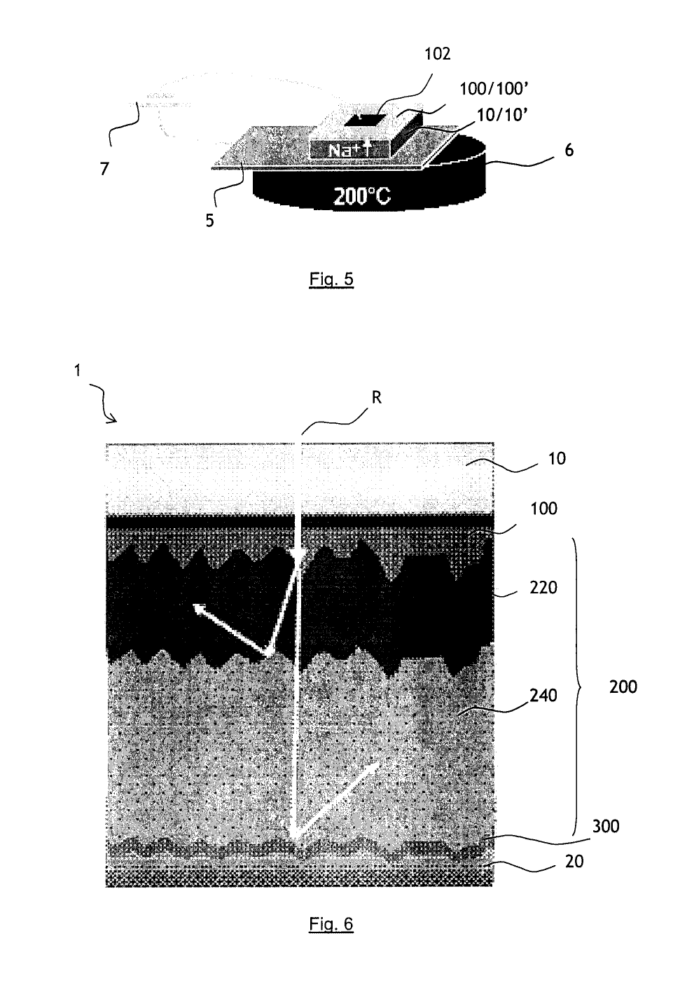

FIG. 6 illustrates a cross-sectional diagram of a photovoltaic cell.

In FIGS. 1, 2, 5 and 6, the proportions of the thicknesses of the various coatings, layers and materials have not been strictly respected so as to make them easier to examine.

FIG. 1 illustrates a photovoltaic cell front face substrate 10′ of the prior art having an absorbent photovoltaic material 200, said substrate 10′ having, on a main surface, a transparent electrode coating 100′ consisting of a TCO layer 66 that conducts the current.

The front face substrate 10′ is placed in the photovoltaic cell in such a way that said front face substrate 10′ is the first substrate through which the incident radiation R passes before reaching the photovoltaic material 200.

The substrate 10′ also includes, beneath the electrode coating 100′, i.e. directly on the substrate 10′, a base antireflection layer 15 having a refractive index n₁₅ lower than that of the substrate.

FIG. 2 illustrates a photovoltaic cell front face substrate 10 according to the invention.

The front face substrate 10 also has on a main surface a transparent electrode coating 100, but here this electrode coating 100 consists of a thin-film stack comprising a metallic functional layer 40, based on silver, and at least two antireflection coatings 20, 60, said coatings each comprising at least one thin antireflection layer 24, 26; 64, 66, said functional layer 40 being placed between the two antireflection coatings, one called the subjacent antireflection coating 20 located beneath the functional layer, in the direction of the substrate, and the other called the superjacent antireflection coating 60 located above the functional layer, in the opposite direction to the substrate.

The thin-film stack constituting the transparent electrode coating 100 of FIG. 2 has a stack structure of the type of that of a low-E substrate, optionally toughenable or to be toughened, with a functional monolayer, such as may be found commercially for applications in the field of architectural glazing for buildings.

Twelve examples, numbered 1 to 12, were produced on the basis of the stack structure with a functional monolayer illustrated:
in the case of examples 1, 2; 5, 6; 9, 10 on the basis of FIG. 1; and
in the case of examples 3, 4; 7, 8; 11, 12 on the basis of FIG. 2, except that the stack does not include a blocking overcoating.

Moreover, in all the examples below, the thin-film stack is deposited on a substrate 10 made of clear soda-lime glass 4 mm in thickness.

The electrode coating 100′ of the examples according to FIG. 1 are based on conductive aluminum-doped zinc oxide.

Each stack constituting an electrode coating 100 of the examples according to FIG. 2 consists of a thin-film stack comprising:
an antireflection layer 24, which is a dielectric layer based on titanium oxide, with an index n=2.4;
an antireflection layer 26, which is a dielectric oxide-based wetting layer, especially one based on optionally doped zinc oxide, with an index n=2;
optionally, a subjacent blocking coating (not illustrated), for example based on Ti or based on an NiCr alloy that could be placed directly beneath the functional layer 40, but is not provided here; this coating is in general necessary if there is no wetting layer 26, but is not necessarily essential;
the single functional layer 40, made of silver, is thus placed here directly on the wetting coating 26;
a superjacent blocking coating 50 based on Ti or based on an NiCr alloy could be placed directly on the functional layer 40, but is not provided in the examples produced;
a dielectric antireflection layer 64, based on zinc oxide, with an index n=2 and a resistivity of the order of 100 Ω·cm, this layer being deposited here from a ceramic target directly on the blocking coating 50; and then
a layer 66 that conducts the current, which is an antireflection layer and terminal layer, based on aluminum-doped zinc oxide, with an index n=2, is furthermore provided, its resistivity being substantially close to 1100 μΩ·cm.

In the even-numbered examples the photovoltaic material 200 is based on microcrystalline silicon (the crystallite size of which is of the order of 100 nm), whereas in the odd-numbered examples the photovoltaic material 200 is based on amorphous (i.e. noncrystalline) silicon.

The quantum efficiency QE of these materials is illustrated in FIG. 3 together with that of cadmium telluride—another photovoltaic material that is also suitable within the context of the invention.

It will be recalled here that the quantum efficiency QE is, as is known, the expression for the probability (between 0 and 1) of an incident photon with a wavelength given on the x-axis being transformed into an electron-hole pair.

As may be seen in FIG. 3, the maximum absorption wavelength λₘ, i.e. the wavelength at which the quantum efficiency is a maximum (i.e. at its highest value):
of amorphous silicon a-Si, i.e. λₘ(a-Si), is 520 nm;
of microcrystalline silicon μc-Si, i.e. λₘ (μc-Si), is 720 nm; and
of cadmium telluride CdTe, i.e. λₘ(CdTe), is 600 nm.

To a first approximation, this maximum absorption wavelength λₘ is sufficient.

The antireflection coating 20 placed beneath the metallic functional layer 40 in the direction of the substrate therefore has an optical thickness equal to about one eight of the maximum absorption wavelength λₘ of the photovoltaic material and the antireflection coating 60 placed above the metallic functional layer 40 on the opposite side from the substrate then has an optical thickness equal to about one half of the maximum absorption wavelength λₘ of the photovoltaic material.

Table 1 below summarizes the preferred ranges of the optical thicknesses in nm for each coating 20, 60 and for these three materials.

TABLE 1

| Material | | a-Si | μc-Si | CdTe |
|---|---|---|---|---|
| Coating | λₘ/2 | 260 | 360 | 300 |
| 60 | 0.45λₘ | 234 | 324 | 270 |
| | 0.55λₘ | 286 | 396 | 330 |
| Coating | λₘ/8 | 65 | 90 | 75 |
| 20 | 0.075λₘ | 39 | 54 | 45 |
| | 0.175λₘ | 91 | 126 | 105 |

However, it has been found that the optical definition of the stack may be improved by considering the quantum efficiency in order to obtain an improved actual yield by convoluting this probability by the wavelength distribution of the solar light at the surface of the Earth. Here, we use the normalized solar spectrum AM1.5.

In this case, the antireflection coating 20 placed beneath the metallic functional layer 40 in the direction of the substrate has an optical thickness equal to about one eighth of the maximum wavelength λ_{M} of the product of the absorption spectrum of the photovoltaic material multiplied by the solar spectrum and the antireflection coating 60 placed above the metallic functional layer 40 on the opposite side from the substrate has an optical thickness equal to about one half of the maximum wavelength λ_{M} of the product of the absorption spectrum of the photovoltaic material multiplied by the solar spectrum.

As may be seen in FIG. 4, the maximum wavelength λ_{M} of the product of the absorption spectrum of the photovoltaic material multiplied by the solar spectrum, i.e. the wavelength at which the yield is a maximum (i.e. at its highest value):
of amorphous silicon a-Si, i.e. λ_{M}(a-Si), is 530 nm;
of microcrystalline silicon μc-Si, i.e. λ_{M}(μc-Si), is 670 nm; and
of cadmium telluride CdTe, i.e. λ_{M}(CdTe), is 610 nm.

Table 2 below summarizes the preferred ranges of the optical thicknesses in nm for each coating 20, 60 and for each of these three materials.

TABLE 2

| Material | | a-Si | μc-Si | CdTe |
|---|---|---|---|---|
| Coating | λ_{M}/2 | 265 | 335 | 305 |
| 60 | 0.45λ_{M} | 239 | 302 | 275 |
| | 0.55λ_{M} | 292 | 369 | 336 |
| Coating | λ_{M}/8 | 66 | 84 | 76 |
| 20 | 0.075λ_{M} | 40 | 50 | 46 |
| | 0.175λ_{M} | 93 | 117 | 107 |

In all the examples, a base antireflection layer 15 based on silicon oxide was deposited between the substrate and the electrode coating 100. Since its refractive index n₁₅ is low and close to that of the substrate, its optical thickness has not been taken into account in the definition of the optical path of the stack according to the invention.

The conditions under which these layers are deposited are known to those skilled in the art since they are stacked similar to those used for low-emissivity or solar-control applications.

In this regard, a person skilled in the art may refer to patent applications EP 718 250, EP 847 965, EP 1 366 001, EP 1 412 300 or EP 722 913.

Tables 3, 5 and 7 below summarize the materials and the physical thicknesses measured in nanometers of each of the layers of each of examples 1 to 12 and Tables 4, 6 and 8 present the main characteristics of these examples.

The performance characteristic P is calculated by what is called the “TSQE” method in which the product of the integration of the spectrum over the entire radiation range in question with the quantum efficiency QE of the cell is used.

All the examples 1 to 12 were subjected to a test for measuring the resistance of the electrode coatings to the stresses generated during operation of the cell (especially the presence of an electrostatic field), made in accordance with that illustrated in FIG. 5.

For this test, a portion of the substrate 10, 10′, for example measuring 5 cm×5 cm and coated with the electrode coating 100, 100′, but without the photovoltaic material 200, is deposited on a metal plate 5 placed on a heat source 6 at about 200° C.

The test involves applying an electric field to the substrate 10, 10′ coated with the electrode coating 100, 100′ for 20 minutes, an electrical contact 102 being produced on the surface of said coating, and this contact 102 and the metal plate 5 being connected to the terminals of a power supply 7 delivering a DV current at about 200 V.

At the end of the test, once the specimen has cooled, the percentage of coating remaining is measured over the entire surface of this specimen.

This percentage of coating remaining after the resistance test is denoted by % CR.

### FIRST SERIES OF EXAMPLES

TABLE 3

| Layer/material | Ex. 1 | Ex. 2 | Ex. 3 | Ex. 4 |
|---|---|---|---|---|
| 200: μc-Si (Ex. 1 | 1500 | 710 | 720 | 1500 |
| and 3) or a-Si (Ex. | | | | |
| 2 and 4) | | | | |
| 66: ZnO:Al | 1020.6 | 1020.6 | 129.3 | 129.3 |
| 64: ZnO | | | 6 | 6 |
| 40: Ag | | | 7 | 7 |
| 26: ZnO | | | 7 | 7 |
| 24: TiO₂ | | | 24.3 | 24.3 |
| 15: SiO₂ | 110 | 110 | 110 | 110 |

TABLE 4

| | | | |
|---|---|---|---|
| Ex. 1 | Ex. 2 | Ex. 3 | Ex. 4 |

| | | |
|---|---|---|
| R_{□}(ohms/_{□}) | 10.9 | 7.4 |

| | | | | |
|---|---|---|---|---|
| P(%) | 88.1 | 82.4 | 86.3 | 87.2 |
| % CR | 73 | 65 | 99 | 100 |

In this first series, the optical thickness of the coating 60 above the functional metallic layer is 270.6 nm (=(129.3+6)×2) and the optical thickness of the coating 20 below the functional metallic layer is 72.32 nm (=24.3×2.4+7×2).

In this series, the antireflection coating 60 has an optical thickness equal to 3.74 times the optical thickness of the antireflection coating 20.

This first series shows that it is possible to obtain an electrode coating consisting of a thin-film stack and coated with amorphous silicon (Example 4), which has a better (3.5 ohms/□ lower) resistance per square R_{□} and a better (4.8% higher) performance P than a TCO electrode coating coated with the same amorphous material (Example 2). The optical thicknesses of the coatings 20 and 60 of Example 4 fall within the acceptable ranges for an a-Si photovoltaic material 200 according to Tables 1 and 2. However, the optical thicknesses of the coatings 20 and 60 are respectively closer to the λ_{M}/8 and λ_{M}/2 values in Table 2 than the λₘ/8 and λₘ/2 values in Table 1.

In this series, the resistance per square R_{□} of the electrode coating consisting of a thin-film stack and coated with microcrystalline silicon (Example 3) is also better, but the performance P is less good (1.8% lower) than those of the TCO electrode coating coated with the same microcrystalline material (Example 1). The 270.6 nm optical thickness of the coating 60 of Example 3 does not fall within the 324-396 nm range acceptable for a μc-Si photovoltaic material 200 according to Table 1 nor a fortiori within the 302-369 nm range acceptable for a μc-Si photovoltaic material 200 according to Table 2.

Moreover, the percentage of thin-film stack electrode coating remaining after the resistance test (Examples 3 and 4) is much higher, irrespective of the photovoltaic material, than the percentage of TCO electrode coating remaining after the resistance test (Examples 1 and 2).

### SECOND SERIES OF EXAMPLES

TABLE 5

| Layer/material | Ex. 5 | Ex. 6 | Ex. 7 | Ex. 8 |
|---|---|---|---|---|
| 200: μc-Si (Ex. 5 | 1490 | 690 | 1510 | 700 |
| and 7) or a-Si (Ex. | | | | |
| 6 and 8) | | | | |
| 66: ZnO:Al | 1094.6 | 1094.6 | 166.6 | 166. 6 |
| 64: ZnO | — | — | 6 | 6 |
| 40: Ag | — | — | 7 | 7 |
| 26: ZnO | — | — | 7 | 7 |
| 24: TiO₂ | — | — | 39 | 39 |
| 15: SiO₂ | 110 | 110 | 110 | 110 |

TABLE 6

| | | | |
|---|---|---|---|
| Ex. 5 | Ex. 6 | Ex. 7 | Ex. 8 |

| | | |
|---|---|---|
| R_{□}(ohms/□) | 10.2 | 7.2 |

| | | | | |
|---|---|---|---|---|
| P(%) | 88 | 82.4 | 94 | 69.3 |
| % CR | 79% | 82% | 100% | 100% |

In this second series, the optical thickness of the coating 60 above the functional metallic layer is 345 nm (=(166.6+6)×2) and the optical thickness of the coating 20 below the functional metallic layer is 107.6 nm (=39×2.4+7×2).

In this series, the antireflection coating 60 has an optical thickness equal to 3.2 times the optical thickness of the antireflection coating 20.

Unlike the first series, the second series shows that it is possible to obtain an electrode coating consisting of a thin-film stack coated with microcrystalline silicon (Example 7), which has a better (3 ohms/□ lower) resistance per square R_{□} and a better (6% higher) performance P than a TCO electrode coating coated with the same microcrystalline material (Example 5). The optical thicknesses of the coatings 20 and 60 of Example 7 fall within the ranges acceptable for a μc-Si photovoltaic material 200 according to Table 1 and Table 2. However, the optical thickness of the coating 60 is closer to the μc-Si λ_{M}/2 value in Table 2 than the λₘ/2 value in Table 1.

In this series, the resistance per square R_{□} of the electrode coating consisting of a thin-film stack and coated with amorphous silicon (Example 8) is also better, but the performance P is less good (13.1% lower) than those of the TCO electrode coating coated with the same amorphous material (Example 6). The 345 nm optical thickness of the coating 60 and the 107.6 nm optical thickness of the coating 20 of Example 8 do not fall within the 234-286 nm and 39-91 nm ranges respectively acceptable for an a-Si photovoltaic material 200 according to Table 1 nor a fortiori within the 239-292 nm and 40-93 nm ranges respectively acceptable for an a-Si photovoltaic material 200 according to Table 2.

Moreover, the percentage of thin-film stack electrode coating remaining after the resistance test (Examples 7 and 8) is much higher, irrespective of the photovoltaic material, than the percentage of TCO electrode coating remaining after the resistance test (Examples 5 and 6).

### THIRD SERIES OF EXAMPLES

TABLE 7

| Layer/material | Ex. 9 | Ex. 10 | Ex. 11 | Ex. 12 |
|---|---|---|---|---|
| 200: μc-Si (Ex. 9 | 1460 | 720 | 1480 | 702 |
| and 11) or a-Si (Ex. | | | | |
| 10 and 12) | | | | |
| 66: ZnO:Al | 1117.4 | 1117.4 | 107 | 107 |
| 64: ZnO | — | — | 6 | 6 |
| 40: Ag | — | — | 7.2 | 7.2 |
| 26: ZnO | — | — | 7 | 7 |
| 24: TiO₂ | — | — | 21.5 | 21.5 |
| 15: SiO₂ | 110 | 110 | 110 | 110 |

TABLE 8

| | | | |
|---|---|---|---|
| Ex. 9 | Ex. 10 | Ex. 11 | Ex. 12 |

| | | |
|---|---|---|
| R_{□}(ohms/□) | 10 | 7.1 |

| | | | | |
|---|---|---|---|---|
| P(%) | 88 | 82.4 | 76.4 | 92 |
| % CR | 78% | 85% | 100% | 96% |

In this third series, the optical thickness of the coating 60 above the functional metallic layer is 266 nm (=(107+6)×2) and the optical thickness of the coating 20 below the functional metallic layer is 65.6 nm (=21.5×2.4+7×2).

In this series, the antireflection coating 60 has an optical thickness equal to 4.05 times the optical thickness of the antireflection coating 20.

As in the case of the first series, the third series shows that it is possible to obtain an electrode coating consisting of a thin-film stack and coated with amorphous silicon (Example 12), which has a better (2.9 ohms/□ lower) resistance per square R_{□} and a better (9.6% higher) performance P than a TCO electrode coating coated with the same amorphous material (Example 10). The optical thicknesses of the coatings 20 and 60 of Example 12 fall within the ranges acceptable for an a-Si photovoltaic material 200 according to Table 1 and Table 2. However, the optical thicknesses of the coatings 20 and 60 respectively are closer to the λ_{M}/8 and λ_{M}/2 values of Table 2 than the λₘ/8 and λₘ/2 values of Table 1. These optical thicknesses of the coatings 20 and 60 of Example 12 are also practically identical to the λ_{M}/8 and λ_{M}/2 values respectively of Table 2.

In this series, the resistance per square R_{□} of the electrode coating consisting of a thin-film stack and coated with microcrystalline silicon (Example 11) is also better, but the performance P is less good (11.6% lower) than those of the TCO electrode coating coated with the same microcrystalline material (Example 9). The 266 nm optical thickness of the coating 60 of Example 11 does not fall within the 324-396 nm range acceptable for a μc-Si photovoltaic material 200 according to Table 1 nor a fortiori within the 302-369 nm range acceptable for a μc-Si photovoltaic material 200 according to Table 2.

Moreover, the percentage of thin-film stack electrode coating remaining after the resistance test (Examples 11 and 12) is much higher, irrespective of the photovoltaic material, than the percentage of TCO electrode remaining after the resistance test (Examples 9 and 10).

By comparing this third series with the first series, it may be noted that the optical thicknesses of the coatings 20 and 60 of Example 12 (65.6 nm and 266 nm respectively) are closer to the ideal theoretical values for a-Si (65 nm and 260 nm considering λₘ and 66 nm and 265 nm considering λ_{M}, respectively) than those of Example 4 (72.3 nm and 270.6 nm respectively) and that the performance of Example 12 is higher (by 4.8%) for practically the same resistance per square R_{□} and for practically the same % CR, i.e. the percentage of thin-film stack electrode coating remaining after the resistance test.

This third series thus confirms the fact that it is preferable for the antireflection coating 20 placed beneath the metallic functional layer 40 in the direction of the substrate to have an optical thickness equal to about one eighth of the maximum wavelength λ_{M} of the product of the absorption spectrum of the photovoltaic material multiplied by the solar spectrum and for the antireflection coating 60 placed above the metallic functional layer 40 on the opposite side from the substrate to have an optical thickness equal to about one half of the maximum wavelength λ_{M} of the product of the absorption spectrum of the photovoltaic material multiplied by the solar spectrum.

Furthermore, it is worthwhile pointing out that the thin-film stacks forming the electrode coating within the context of the invention do not necessarily have, in the absolute, a very high transparency.

Thus in the case of Example 3, the light transmission in the visible of the substrate coated only with the stack forming the electrode coating and without the photovoltaic material is 75.3%, whereas the light transmission in the visible of the equivalent example with a TCO electrode coating and without the photovoltaic material, namely that of Example 1, is 85%.

Quite simple stacks, especially because they contain no blocking coating, of the ZnO/Ag/ZnO type or of the SnₓZn_{y}O_{z}/Ag/SnₓZn_{y}O_{z} type (in which x, y and z each denote a number) or else of the ITO/Ag/ITO type, and having the features of the invention, seem a priori to be able to be technically suitable for the intended application, but the third runs the risk of being more expensive than the first two.

FIG. 6 illustrates a photovoltaic cell 1 provided with a front face substrate 10 according to the invention, seen in cross section, through which incident radiation R penetrates, and with a backplate substrate 20.

The photovoltaic material 200, for example made of amorphous silicon or crystalline or microcrystalline silicon or else cadmium telluride or copper indium diselenide (CuInSe₂, or CIS) or copper indium gallium selenium, is located between these two substrates. It consists of a layer of n-doped semiconductor material 220 and a layer of p-doped semiconductor material 240 that will produce the electrical current. The electrode coatings 100, 300, inserted respectively between, on the one hand, the front face substrate 10 and the layer of n-doped semiconductor material 220 and, on the other hand, between the layer of p-doped semiconductor material 240 and the backplate substrate 20 complete the electrical structure.

The electrode coating 300 may be based on silver or aluminum, or it may also consist of a thick-film stack having at least one metallic functional layer and in accordance with the present invention.

The present invention has been described in the foregoing by way of example. Of course, a person skilled in the art is capable of producing various alternative forms of the invention without thereby departing from the scope of the patent as defined by the claims.

1. A photovoltaic cell (1) having an absorbent photovoltaic material, said cell comprising a transparent front face substrate (10), having, on a main surface, a transparent electrode coating (100) consisting of a thin-film stack that includes a metallic functional layer (40), and at least two antireflection coatings (20, 60), said antireflection coatings each comprising at least one antireflection layer (24, 26; 64, 66), said functional layer (40) being placed between the two antireflection coatings (20, 60), wherein the antireflection coating (20) placed beneath the metallic functional layer (40) in the direction of the substrate has an optical thickness equal to about one eighth of the maximum absorption wavelength λₘ of the photovoltaic material and the antireflection coating (60) placed above the metallic functional layer (40) on the opposite side from the substrate has an optical thickness equal to about one half of the maximum absorption wavelength λₘ of the photovoltaic material.

2. The photovoltaic cell (1) as claimed in claim 1, wherein the antireflection coating (20) placed beneath the metallic functional layer (40) in the direction of the substrate has an optical thickness equal to about one eighth of the maximum wavelength λ_{M} of the product of the absorption spectrum of the photovoltaic material multiplied by the solar spectrum and the antireflection coating (60) placed above the metallic functional layer (40) on the opposite side from the substrate has an optical thickness equal to about one half of the maximum wavelength λ_{M} of the product of the absorption spectrum of the photovoltaic material multiplied by the solar spectrum.

3. The photovoltaic cell (1) as claimed in claim 1, wherein the electrode coating (100) comprises a layer that conducts a current (66) furthest away from the substrate, having a resistivity ρ of between 2×10⁻⁴ Ω·cm and 10 Ω·cm.

4. The photovoltaic cell (1) as claimed in claim 3, wherein said layer that conducts the current has an optical thickness representing between 50 and 98% of the optical thickness of the antireflection coating (60) furthest away from the substrate.

5. The photovoltaic cell (1) as claimed in claim 1, wherein said antireflection coating (60) placed above the metallic functional layer (40) has an optical thickness of between 0.45 and 0.55 times the maximum absorption wavelength λₘ of the photovoltaic material, these values being inclusive.

6. The photovoltaic cell (1) as claimed in claim 1, wherein said antireflection coating (20) placed beneath the metallic functional layer (40) has an optical thickness of between 0.075 and 0.175 times the maximum absorption wavelength λₘ of the photovoltaic material, these values being inclusive.

7. The photovoltaic cell (1) as claimed in claim 1, wherein said substrate (10) comprises, beneath the electrode coating (100), a base antireflection layer (15) having a low refractive index n₁₅ close to that of the substrate that is formed of silicon oxide, aluminum oxide of a combination thereof.

8. The photovoltaic cell (1) as claimed in claim 7, wherein said base antireflection layer (15) has a physical thickness of between 10 and 300 nm.

9. The photovoltaic cell (1) as claimed in claim 1, wherein the functional layer (40) is placed above a wetting layer (26) based on an oxide.

10. The photovoltaic cell (1) as claimed in claim 1, wherein the functional layer (40) is placed directly on at least subjacent blocking coating (30) and/or directly beneath at least one superjacent blocking coating (50).

11. The photovoltaic cell (1) as claimed in claim 10, wherein at least one blocking coating (30, 50) is formed from Ni, a Ni—Ti alloy or a NiCr alloy.

12. The photovoltaic cell (1) as claimed in claim 1, wherein the coating (20) beneath the metallic functional layer in the direction of the substrate and/or the coating (60) above the metallic functional layer comprises a layer based on a mixed oxide.

13. The photovoltaic cell (1) as claimed in claim 1, wherein the coating (20) beneath the metallic functional layer in the direction of the substrate and/or the coating (60) above the metallic functional layer comprises a layer having a very high refractive index.

14. The photovoltaic cell (1) as claimed in claim 1, which comprises a coating (200) based on a photovoltaic material above the electrode coating (100) on the opposite side from the front face substrate (10).

15. The photovoltaic cell (1) as claimed in claim 1, wherein said electrode coating (100) consists of a toughenable stack or a stack to be toughened, each for an architectural glazing.

16. A substrate (10) coated with a thin-film stack for a photovoltaic cell (1) as claimed in claim 1, said thin-film stack comprising a metallic functional layer (40), and at least two antireflection coatings (20, 60), said antireflection coatings each comprising at least one antireflection layer (24, 26; 64, 66), said functional layer (40) being placed between the two antireflection coatings (20, 60), wherein the antireflection coating (20) placed beneath the metallic functional layer (40) in the direction of the substrate has an optical thickness equal to about one eighth of the maximum absorption wavelength λₘ of the photovoltaic material and the antireflection coating (60) placed above the metallic functional layer (40) on the opposite side from the substrate has an optical thickness equal to about one half of the maximum absorption wavelength λₘ of the photovoltaic material.

17. A method, comprising:
coating a substrate on having a front face with a thin-film stack for producing a front face substrate (10) of a photovoltaic cell (1), as claimed in claim 1, said substrate having a transparent electrode coating (100) consisting of a thin-film stack comprising a metallic functional layer (40), and at least two antireflection coatings (20, 60), said antireflection coatings each comprising at least one thin antireflection layer (24, 26; 64, 66), said functional layer (40) being placed between the two antireflection coatings (20, 60), the antireflection coating (20) placed beneath the metallic functional layer (40) in the direction of the substrate having an optical thickness equal to about one eighth of the maximum absorption wavelength of the photovoltaic material and the antireflection coating (60) placed above the metallic functional layer (40) on the opposite side from the substrate having an optical thickness equal to about one half of the maximum absorption wavelength of the photovoltaic material, thereby producing a front face substrate (10) of a photovoltaic cell.

18. The method as claimed in claim 17 in which wherein the substrate (10) having the electrode coating (100) is a toughenable substrate or a substrate to be toughened, each for architectural glazing.

19. The method as claimed in claim 17 in which said electrode coating (100) comprises a layer (66) which conducts electrical current, and which is furthest from the substrate and has a resistivity ρ of between 2×10⁻⁴ Ω·cm and 10 Ω·cm.

20. The method as claimed in claim 19, in which said layer that conducts electrical current has an optical thickness representing between 50 and 98% of the optical thickness of the antireflection coating (60) furthest away from the substrate.
